(19) United States
(12) Patent Application Publication
(10) Pub. No.: US 2026/0026408 A1
(43) Pub. Date: Jan. 22, 2026

(54) RECONSTITUTED WAFER-SCALE DEVICES USING SEMICONDUCTOR STRIPS

(71) Applicant: Lightmatter, Inc., Boston, MA (US)

(72) Inventors: Mitul Modi, Phoenix, AZ (US); Krishna Bharath, Portland, OR (US); Kuang Liu, Queen Creek, AZ (US); Sandeep Sane, Chandler, AZ (US)

(73) Assignee: Lightmatter, Inc., Boston, MA (US)

(21) Appl. No.: 19/275,805

(22) Filed: Jul. 21, 2025

Related U.S. Application Data
(60) Provisional application No. 63/674,204, filed on Jul. 22, 2024.

(51) Int. Cl. H01L 25/18; G02B 6/42; G02B 6/43; H01L 21/66; H01L 21/683; H01L 21/78; H01L 23/00

(52) U.S. Cl. CPC H01L 25/18; G02B 6/4244; G02B 6/4245; G02B 6/43; H01L 21/6836; H01L 21/78; H01L 22/12; H01L 22/14; H01L 24/32; H01L 24/83; H01L 2221/68354; H01L 2221/68381; H01L 2224/32137; H01L 2224/83005; H01L 2924/37001

(57) ABSTRACT

Described herein are manufacturing techniques and packages that enable wafer-scale heterogenous integration of electronic integrated circuits (EIC) with photonic integrated circuits (PIC) using a reconstitution-based fabrication approach. Wafer-scale photonic devices are formed by assembling strips of known-good dies (KGD). Such strips include arrays of adjacent reticles that have been singulated from a wafer. A strip can include a single row (or column) of reticles singulated from a wafer or multiple rows (or columns) that are adjacent to one another, enabling two-dimensional assembly and increased coverage. Wafer reconstitution involves transferring and bonding one or more strips of KGDs to a target substrate. A KGD is a reticle that is not part of an exclusion zone and has been verified to work properly. Thus, a reconstituted wafer includes strips that have verified to be fully functional.

### CROSS-REFERENCE TO RELATED APPLICATION

This application claims the benefit under 35 U.S.C. §119(e) of U.S. Provisional Application Ser. No. 63/674,204, filed on Jul. 22, 2024, under Attorney Docket No. L0858.70092US00 and entitled “RECONSTITUTED WAFER-SCALE DEVICES USING SEMICONDUCTOR STRIPS,” which is hereby incorporated herein by reference in its entirety.

### BACKGROUND

Photonic integrated circuits (PICs) have emerged as a key technology for advancing the performance of modern computing and communication systems. By leveraging the high-speed and low-loss properties of light, PICs enable the transmission and processing of data at significantly higher bandwidths and lower latencies compared to conventional electronic interconnects. In addition, PICs support scalable architectures by facilitating parallel optical links that can be integrated alongside electronic circuitry. As a result, PICs are increasingly being adopted in data centers, artificial intelligence (AI) accelerators, high-performance computing (HPC), and other bandwidth-intensive applications.

### BRIEF SUMMARY

In some aspects, the techniques described herein relate to a photonic device, including: a plurality of strips, each of the plurality of strips including a plurality of contiguous reticles collectively forming a continuous photonic network, wherein the plurality of strips are extracted from one or more source wafers; and a filling material disposed between the plurality of strips.

In some aspects, the techniques described herein relate to a photonic device, wherein the filling material surrounds the plurality of strips.

In some aspects, the techniques described herein relate to a photonic device, wherein the filling material has a rounded edge profile where the filling material surrounds the plurality of strips.

In some aspects, the techniques described herein relate to a photonic device, wherein a first strip of the plurality of strips extends along a first axis and a second strip of the plurality of strips extends along a second axis perpendicular to the first axis.

In some aspects, the techniques described herein relate to a photonic device, further including: a substrate, wherein the plurality of strips are adhered to the substrate, wherein the substrate includes a carrier wafer or an electronic integrated circuit (EIC).

In some aspects, the techniques described herein relate to a device, wherein the plurality of strips includes: a first subset of strips of a first type; and a second subset of strips of a second type, where the first type is different from the second type.

In some aspects, the techniques described herein relate to a photonic device, including: a plurality of strips, each of the plurality of strips including a plurality of contiguous reticles collectively forming a continuous photonic network, wherein the plurality of strips includes at least a first strip extracted from a first source wafer and a second strip extracted from a second source wafer, wherein the first strip includes an intra-strip coupler optically coupling a first reticle of the first strip to a second reticle of the first strip; and an inter-strip coupler optically coupling the first strip to the second strip.

In some aspects, the techniques described herein relate to a photonic device, further including a filling material surrounding the plurality of strips.

In some aspects, the techniques described herein relate to a photonic device, wherein the filling material has a rounded edge profile where the filling material surrounds the plurality of strips.

In some aspects, the techniques described herein relate to a photonic device, wherein a portion of the filling material is disposed between the first strip and the second strip and forms part of the inter-strip coupler.

In some aspects, the techniques described herein relate to a photonic device, further including: a substrate, wherein the plurality of strips are adhered to the substrate, wherein the substrate includes a carrier wafer or an electronic integrated circuit (EIC).

In some aspects, the techniques described herein relate to a photonic device, wherein the first strip is of a first type and the second strip is of a second type different from the first type.

In some aspects, the techniques described herein relate to a photonic device, wherein: the first strip of the first type includes a v-groove; and the second strip of the second type lacks v-grooves.

In some aspects, the techniques described herein relate to a method of manufacturing a photonic device, the method including: fabricating a first silicon wafer including a first plurality of reticles; testing each of the first plurality of reticles to identify functional reticles; singulating a first plurality of strips from the first silicon wafer, wherein each of the first plurality of strips includes a plurality of functional reticles from among the identified functional reticles; and forming a continuous photonic network by attaching the first plurality of strips together.

In some aspects, the techniques described herein relate to a method, further including: fabricating a second silicon wafer including a second plurality of reticles; testing each of the second plurality of reticles to identify functional reticles; and singulating a second plurality of strips from the second silicon wafer, wherein each of the second plurality of strips includes a plurality of functional reticles of the identified functional reticles of the second silicon wafer; wherein forming the continuous photonic network includes attaching the first plurality of strips to the second plurality of strips.

In some aspects, the techniques described herein relate to a method, wherein attaching the first plurality of strips together includes: adhering the first plurality of strips to a carrier wafer using an adhesive; filling gaps between the first plurality of strips with a filling material; and removing the first plurality of strips and the filling material from the carrier wafer by removing the adhesive.

In some aspects, the techniques described herein relate to a method, wherein removing the plurality of strips and the filling material from the carrier wafer by removing the adhesive includes exposing the adhesive to laser light and/or heating the adhesive.

In some aspects, the techniques described herein relate to a method, wherein filling the gaps between the first plurality of strips with the filling material includes surrounding the first plurality of strips with the filling material.

In some aspects, the techniques described herein relate to a method, wherein surrounding the first plurality of strips with the filling material includes defining a rounded edge profile where the filling material surrounds the first plurality of strips.

In some aspects, the techniques described herein relate to a method, wherein attaching the plurality of strips together includes: attaching the plurality of strips to an electronic integrated circuit (EIC); and filling gaps between the plurality of strips with a filling material.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1 illustrates a wafer having a grid of reticles that are candidates for use in wafer-scale integration.

FIGS. 2A and 2B illustrate an example of a wafer reconstitution process for forming a wafer-scale photonic device using extracted strips of known-good dies (KGD), in accordance with some embodiments.

FIGS. 3A and 3B illustrate an example of a wafer reconstitution process in which KGDs of predetermined sizes are extracted from a source wafer and stitched together to form a reconstituted wafer-scale device tailored for a specific application, in accordance with some embodiments.

FIG. 3C is a cross-sectional view taken along line BB of FIG. 3B, in accordance with some embodiments.

FIGS. 4A and 4B illustrate an example of a wafer reconstitution process in which some of the strips are reoriented, in accordance with some embodiments.

FIGS. 5A and 5B illustrate an example in which a reconstituted wafer is assembled using strips of KGDs extracted from two different source wafers, in accordance with some embodiments.

FIG. 6 illustrates an example method for manufacturing reconstituted wafers using a wafer-to-wafer bonding process, in accordance with some embodiments.

FIGS. 7A and 7B illustrate an example of a die-to-wafer reconstitution process in which strips of KGDs are transferred directly on an electronic integrated circuit (EIC) wafer, in accordance with some embodiments.

FIG. 8 illustrates an example method for manufacturing reconstituted wafers using a die-to-wafer bonding process, in accordance with some embodiments.

FIG. 9 illustrates an example in which waveguides from adjacent strips are optically coupled using an intermediate optical medium, in accordance with some embodiments.

### DETAILED DESCRIPTION

Described herein are manufacturing techniques that enable wafer-scale heterogenous integration of electronic integrated circuits (EIC) with photonic integrated circuits (PIC) using a reconstitution-based fabrication approach.

In current approaches to heterogeneous integration, EICs (such as xPUs and switch dies), are mounted on photolithographically stitched PICs to enable interconnectivity across an entire photonic wafer. This type of integration leverages reticle stitching, a process whereby multiple photonic die patterns are combined across lithographic exposures to form a contiguous photonic circuit spanning large portions of the wafer. A reticle refers to the area on a wafer that can be patterned in a single exposure step during photolithography.

The inventors have recognized and appreciated several constraints limiting the efficiency of this approach. First, limitations arise from exclusion zones. Exclusion zones are regions on the photonic wafer where no devices can be patterned due to photolithographic design rule constraints. Some exclusion zones range from 3 mm to 10 mm from the edge of the wafer. This constraint renders entire rows or columns of reticles unavailable for use.

Second, limitations arise from limited yields, the percentage of functional photonic dies on a wafer, which is as low as 70% in certain semiconductor foundries. Large exclusion zones and poor reticle yield result in substantial underutilization of wafer real estate. In some cases, up to 40% of the reticles on a wafer are rendered unusable, thus reducing the overall computational capacity of a wafer-scale photonic device. Heterogeneous EIC-to-PIC integration is typically confined to within the bounds of a single reticle, restricting system-scale integration and limiting design flexibility.

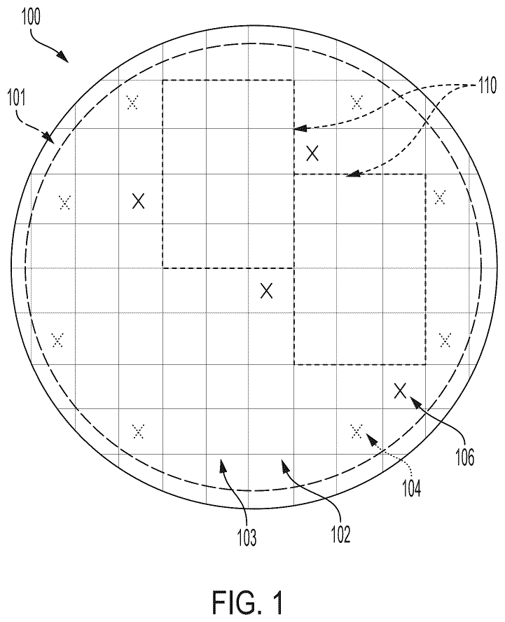

These limitations can be appreciated from the scenario illustrated in FIG. 1, which illustrates a wafer 100 having a grid of reticles that are candidates for use in wafer-scale integration. Wafer 100 has a circular shape and includes multiple reticles arranged in a two-dimensional array. An imaginary boundary line 101 is depicted, representing the lithographically usable region of the wafer. Reticles located entirely within this boundary are fully formed and can potentially be used in assembly. Reticles that extend beyond this boundary are only partially formed due to the curvature of the wafer and are not considered viable for integration. Reticles 102 and 103 represent two known-good dies (KGDs). These are photonic reticles that have been successfully fabricated and tested to confirm functionality. These reticles are candidates for inclusion in a wafer-scale device. Reticles 104 fall within exclusion zones, which are excluded regardless of yield. Reticles 106 are identified as having failed yield criteria, for example due to process defects, misalignment, or damage. These reticles are therefore not usable. Here, the goal is to identify contiguous groups of known-good dies suitable for extraction of functional devices. Specifically, the objective is to extract as many 4×3 reticle blocks as possible. Due to the constraints resulting from excluded reticles 104 and poor-yield reticles 106, only two 4×3 blocks can be successfully extracted.

Third, limitations in silicon photonics foundry processes, such as the inability to customize certain features such as fiber attach units (FAU) etching on a per-reticle basis, further constrain design flexibility and integration. FAUs are often used to interface optical signals from the chip to external fibers. A common technique for aligning and securing these fibers uses v-grooves. However, v-grooves can typically be etched only along two opposing edges of a wafer. This geometric restriction severely constrains the possible locations for optical I/O at the wafer level and limits efficient fiber coupling.

The inventors have developed techniques that address these limitations by introducing a reconstitution-based fabrication approach. In some embodiments, wafer-scale photonic devices are formed by assembling “strips” of known-good dies. The term “strip” indicates an array of adjacent reticles that have been singulated from a wafer. A strip can include a single row (or column) of reticles singulated from a wafer or multiple rows (or columns) that are adjacent to one another, enabling two-dimensional assembly and increased coverage.

Wafer reconstitution involves transferring and bonding one or more strips of KGDs to a target substrate. Each reticle may include a variety of photonic components, such as waveguides, modulators, detectors, multiplexers, switches and couplers. The strips may originate from a single wafer or from multiple wafers, allowing selective use of KGD and enabling customized optical functionality across the reconstituted wafer. A KGD is a reticle that is not part of an exclusion zone and has been verified to work properly. Thus, a reconstituted wafer includes strips that have been verified to be fully functional. In some embodiments, a reconstituted wafer may include strips of varying sizes and/or strips oriented along different axes. This approach facilitates v-groove access on all four sides of the reconstituted wafer, thereby providing enhanced fiber coupling. In some embodiments, strips may be obtained from wafers fabricated in accordance with different optical patterns, facilitating heterogeneous integration of different PIC architectures.

To promote efficient optical coupling across strip boundaries, the reconstitution process may include a step designed to define an oxide or polymer layer (e.g., index-matching epoxy) between adjacent strips. The presence of such a layer reduces the refractive index gap that may otherwise result at the interface, there enhancing optical coupling,

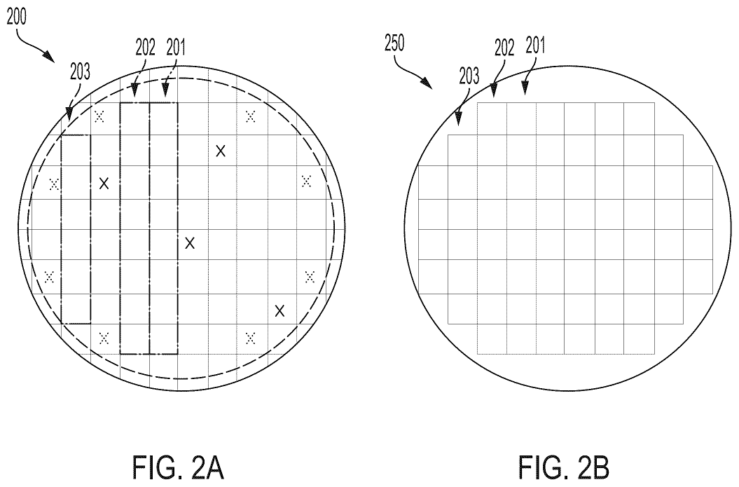

FIGS. 2A and 2B illustrate an example of a wafer reconstitution process for forming a wafer-scale photonic device using extracted strips of KGDs. FIG. 2A shows a source wafer 200 including an array of reticles arranged in a two-dimensional grid. Similar to wafer 100, described in connection with FIG. 1, this wafer includes various reticles, some of which are defective or lie within exclusion zones.

Within source wafer 200, multiple strips 201, 202 and 203 of contiguous KGDs are identified. Each strip includes two or more fully functional reticles that are aligned along a common axis (e.g., the vertical axis in this figure). These strips may be of uniform or varying width and length. These strips are selected based on their verified performance. In this example, strips 201, 202 and 203 are identified as candidates for reconstitution. Once selected, the strips 201, 202 and 203 are singulated from the source wafer and transferred to form a reconstituted wafer 250, shown in FIG. 2B. The reconstituted wafer 250 is formed by bonding or assembling the selected strips on a substrate. The physical size of the reconstituted wafer 250 may match that of the original wafer 200, or it may differ, depending on the desired system architecture. In some embodiments, reconstituted wafer 250 is designed to support fiber coupling at any or all edges using v-grooves.

The reconstitution process enables precise optical stitching between adjacent strips, aligning waveguides and other photonic components across strip boundaries. Optical stitching of strips permits optical continuity across the entire wafer, thereby forming a large-scale PIC. The use of only known-good dies in the reconstituted wafer ensures improved overall yield and enables the design of complex, scalable photonic architectures.

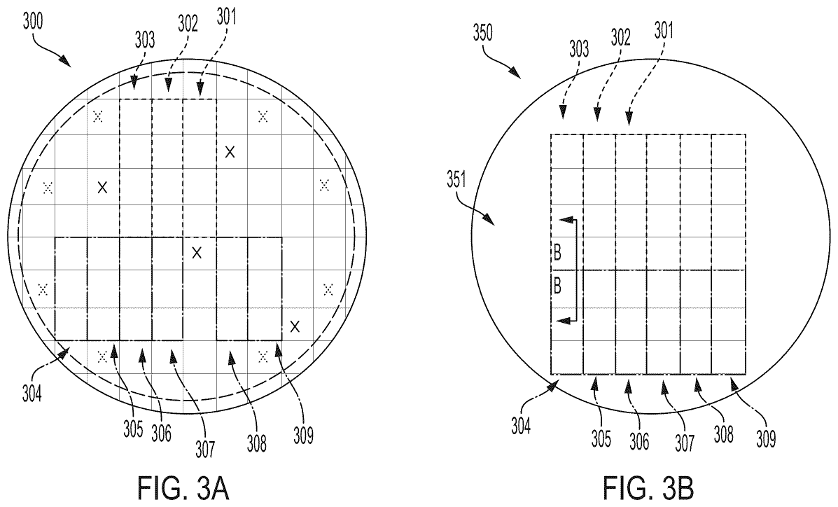

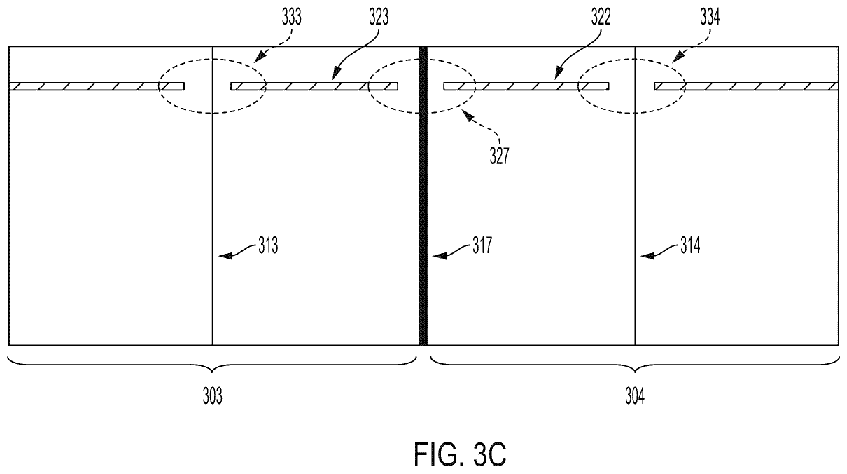

FIGS. 3A and 3B schematically illustrate an example of a wafer reconstitution process in which KGDs of predetermined sizes are extracted from a source wafer and stitched together to form a reconstituted wafer-scale device tailored for a specific application. FIG. 3A shows a source wafer 300 including an array of reticles patterned across its surface. Reference numerals 301, 302, 303, 304, 305, 306, 306, 307, 308 and 309 represent strips of KGDs. Unlike the example of FIG. 2A-2B, where the strip dimensions may be chosen to maximize yield from the available reticle pattern, in the example of FIG. 3A-3B, strips of predefined dimensions are selected, even where larger strips could be extracted. This may be done to meet specific design requirements. For example, strips 301-303 include blocks of 4×1 reticles while strips 304-309 include blocks of 3×1 reticles. As illustrated in FIG. 3B, the selected strips are transferred and bonded to form a reconstituted wafer 350. The reconstituted wafer includes strips 301-309, arranged according to the same layout and sizing as in the wafer 300. In some embodiments, empty spaces within the layout that are not occupied by functional strips may be occupied with structural silicon (also referred to as dummy dies) to support subsequent packaging processes. Sub-reticle regions around the periphery of the device may be filled with a filling material 351 (e.g., a molding material, polymer or oxide fill) to produce a rounded edge profile, thereby allowing the reconstituted wafer to conform to standard wafer handling and packaging tools.

FIG. 3C is a cross-sectional view taken along line BB of FIG. 3B, encompassing portions of strips 303 and 304. Reticle boundaries within each strip are indicated by intra-strip boundaries 313 and 314. The boundary between strips 303 and 304 is identified as inter-strip boundary 317. Photonic networks including waveguides 323 and 322 are formed across the reticles to support optical signal transmission. The waveguides traverse both intra-strip boundaries and inter-strip boundaries, thereby enabling photonic continuity throughout the reconstituted wafer. Within strip 303, intra-strip waveguide coupler 333 (also referred to as an intrinsic coupler) enables optical coupling across reticle boundary 313. Similarly, within strip 304, intra-strip waveguide coupler 334 enables optical coupling across reticle boundary 314. At the strip boundary 317, an inter-strip coupler 327 is provided to optically couple waveguides 323 and 322 across adjacent strips 303 and 304. Use of both intra-strip couplers and inter-strip couplers allows the strips to collectively form continuous photonic networks across the entire wafer-scale device. This approach supports the fabrication of large-scale PICs with seamless waveguide alignment.

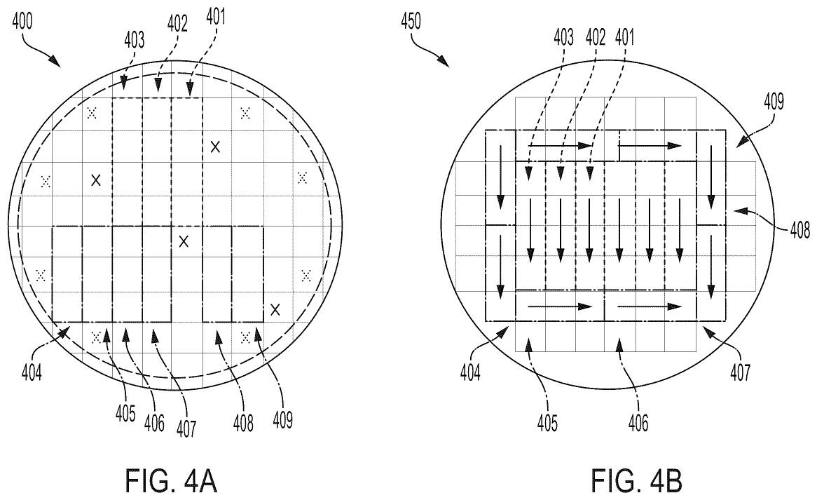

FIG. 4A shows another source wafer 400 in accordance with some embodiments. Strips 401, 402, 403, 404, 405, 406, 407, 408 and 409 represent contiguous groups of KGDs that may be extracted from the source wafer 400. FIG. 4B shows a reconstituted wafer 450 formed by combining the strips 401 through 409. Notably, in this example, some of the strips that were originally oriented vertically in the source wafer (e.g., 405-406) are placed horizontally in the reconstituted wafer. This change in orientation enables greater flexibility in how reticles are optically connected after reconstitution in that it allows for optical interconnection across both horizontal and vertical directions. This approach addresses a limitation of certain foundries that may only support optical stitching in a single direction, typically between vertically adjacent reticles.

The strips described in the previous examples are one reticle wide horizontally and multiple reticles long in the vertical direction. However, any rectangular-shaped strip may be obtained from a wafer. For example, strips may be multiple reticles wide in the vertical direction and the horizontal direction. As a particular example, the strips may also be one reticle long in the vertical direction and multiple reticles wide in the horizontal direction.

In the examples described above, multiple source wafers are used to form one reconstituted wafer, and each source wafer has an identical pattern. The inventors have recognized and appreciated, however, that wafers created using different photomask sets may be used to form more complex wafer-scale devices. This can be useful, for example, when it is desired to define different functions in different portions of a reconstituted wafer. For example, in some applications, it may be desirable for reticles located along the perimeter of the device to include v-grooves to enable fiber coupling, while interior reticles are formed without v-grooves.

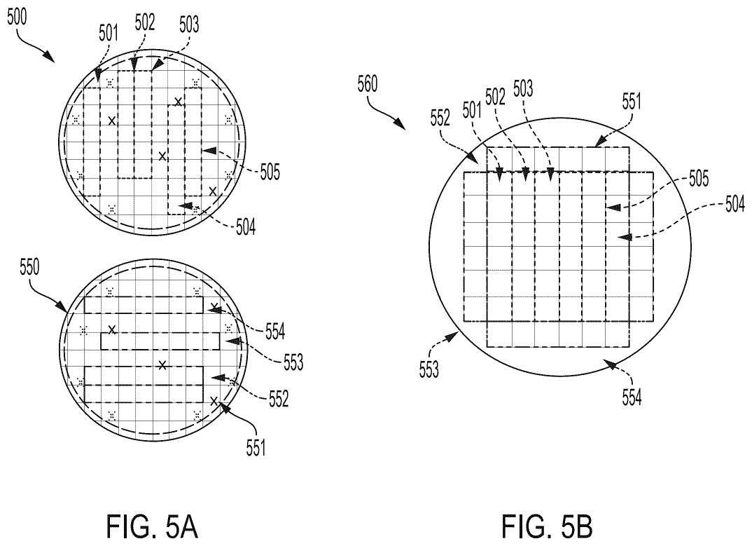

FIGS. 5A and 5B illustrate an example in which a reconstituted wafer is assembled using strips of KGDs extracted from two different source wafers. This approach enables integration of photonic dies having different functionalities and/or formed using different fabrication photomasks. FIG. 5A shows two source wafers 500 and 550. Wafer 500 includes strips 501, 502, 503, 504 and 505. Each strip includes a column of KGDs. Notably, the reticles of wafer 500 are fabricated without v-grooves. These reticles are intended for use in the interior of a reconstituted device and do not require coupling to external optical fibers. Similarly, wafer 550 includes strips 551, 552, 553, and 554. Unlike the strips of wafer 500, however, the strips of wafer 550 include reticles fabricated to define with v-grooves, enabling optical coupling to external fiber sources. Wafers 500 and 550 are fabricated using different mask sets. In FIG. 5B, the selected strips from both source wafers are assembled to form a reconstituted wafer 560. In this example, the interior region of the wafer includes strips 501-505 from wafer 500, while around the perimeter, wafer 560 includes strips 551-554 from wafer 550. This layout enables light to be coupled from external sources into the outer strips, and then be routed optically to the inner dies via integrated photonic waveguides.

In some embodiments, multiple wafers of each type may be used to create enough strips to form the reconstituted wafer. As such, it is contemplated that the process may use multiple wafers of a first type and multiple wafers of a second type to form the reconstituted wafer. Embodiments are also not limited to using only two types of wafers. Any number of wafer types may be used.

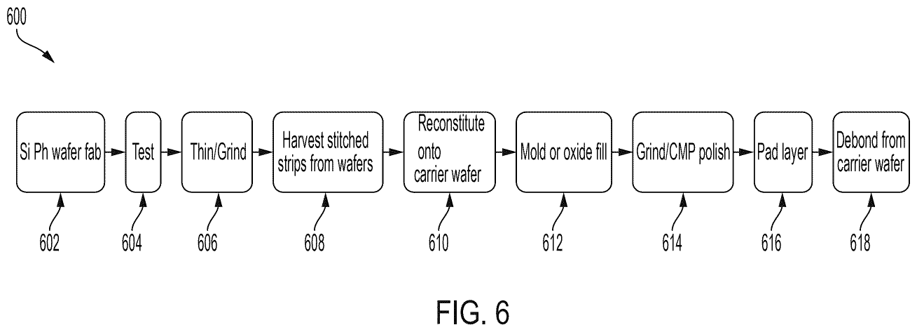

FIG. 6 illustrates an example method for manufacturing reconstituted wafers using a wafer-to-wafer bonding process, according to some embodiments. Method 600 begins at step 602, in which one or more silicon photonics wafers are fabricated. In some embodiments, identical reticle masks are used across the entire wafer, such that each reticle on the wafer is formed using the same photolithographic pattern. In some cases, multiple types of wafers may be fabricated, with each wafer comprising reticles formed using a single mask set.

At step 604, the reticles on each wafer are tested to identify KGDs and to flag non-functional reticles. Testing may include electrical and/or optical probing to ensure that only functional dies are selected for reconstitution.

At step 606, the wafers are processed to prepare for reconstitution. This may include thinning, grinding, and/or dicing the wafer to expose through-silicon vias (TSVs) within the reticles. These steps are typically performed prior to bonding. Dicing results in the formation of strips containing multiple KGDs. As described above, these strips may vary in configuration: for example, they may be one reticle wide and multiple reticles long; one reticle long and multiple reticles wide; or comprise multiple reticles in both width and length.

At step 608, the diced strips are harvested and prepared for placement on a carrier wafer. At step 610, the strips are arranged in a desired configuration on the surface of a carrier wafer. The carrier wafer may be made of glass, silicon, or other suitable material. The strips may be secured using a bonding adhesive or a laser-release layer. In some embodiments, the strips are positioned with their active sides facing upward, away from the surface of the carrier wafer, such that exposed TSVs face downward toward the adhesive and/or carrier wafer, while I/O pads face away from the carrier wafer. Openings between strips may be filled with dummy reticles to maintain wafer topology.

In some examples, a spacing gap between 40 and 100 microns in length may exist between adjacent strips after placement on the carrier wafer. At step 612, these inter-strip gaps are filled using a suitable fill material. In some embodiments, the gaps are filled with a filling material (e.g., an oxide fill or a material formed using a molding process). The filling material may also be applied to peripheral regions of the carrier wafer to create a rounded edge profile. This allows the resulting reconstituted wafer to match the size and shape of a conventional monolithic wafer, enabling compatibility with standard wafer handling tools.

Following the fill step, excess fill material may remain on the surface of the strips. At step 614, the top surface is planarized using grinding and/or chemical mechanical polishing (CMP) to define a uniform surface. In some embodiments, this step also removes any original pads that were present on the active surface of the reticles. At step 616, new pads are formed on the polished surface of the reconstituted wafer. These pads serve as electrical interfaces for further packaging steps. At step 618, the adhesive layer is removed and the reconstituted wafer is released from the carrier wafer. In some embodiments, debonding is performed using a laser release process or thermal activation.

In some embodiments, steps 602, 604, and 606 are carried out at a first facility, while the subsequent steps are performed at a second facility distinct from the first. This division of processing steps may facilitate manufacturing efficiency.

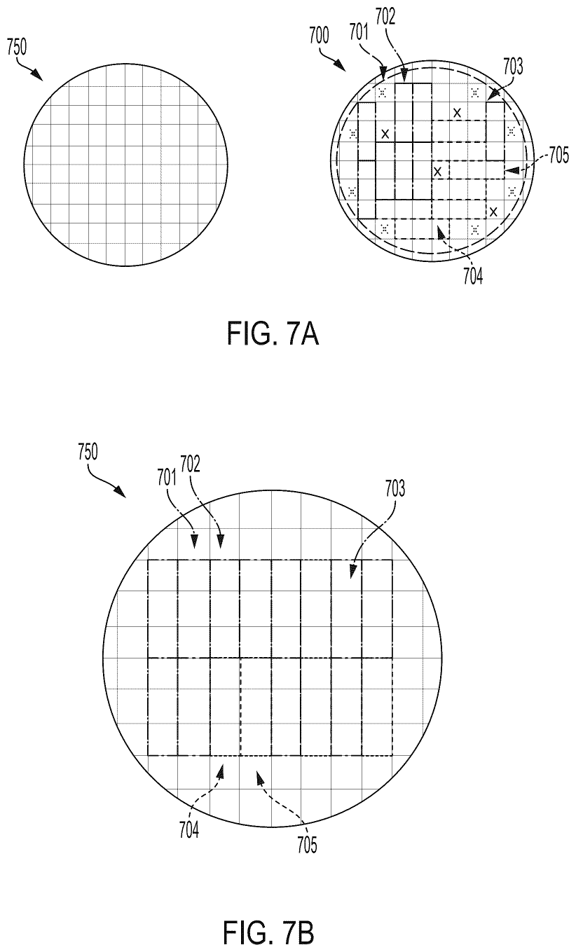

While FIGS. 2-5 illustrate wafer-to-wafer bonding processes in which extracted strips are bonded to a carrier wafer, other embodiments relate to a die-to-wafer process, in which extracted strips are attached directly on an EIC wafer. FIGS. 7A and 7B illustrate an example of a die-to-wafer reconstitution process in which strips of KGDs are transferred directly on an EIC wafer, rather than on a passive carrier wafer. In FIG. 7A, EIC wafer 750 includes a full array of functional electronic dies. These dies may include processors, switches, serializers/deserializers (SerDes) or other electronic components configured to operate in conjunction with photonic elements. FIG. 7A further shows an optical wafer 700. Usable reticles are extracted from wafer 700 in the form of strips 701, 702, 703, 704 and 705.

In FIG. 7B, strips 701 through 705 have been attached directly on the surface of EIC wafer 750. This die-to-wafer approach allows the photonic elements from the optical wafer to be integrated with the electronic logic of the EIC wafer, thereby forming a hybrid electronic-photonic system. The integration enables direct optical interfacing between the photonic strips and underlying EIC structures through, for example, electrical pads.

This die-to-wafer technique supports all of the variations described in connection with FIGS. 2-5. For instance, strips may be selected from multiple optical wafers, including wafers fabricated using different mask sets or processes. Strips may also vary in dimensions or include reticles with distinct features such as v-grooves or internal couplers.

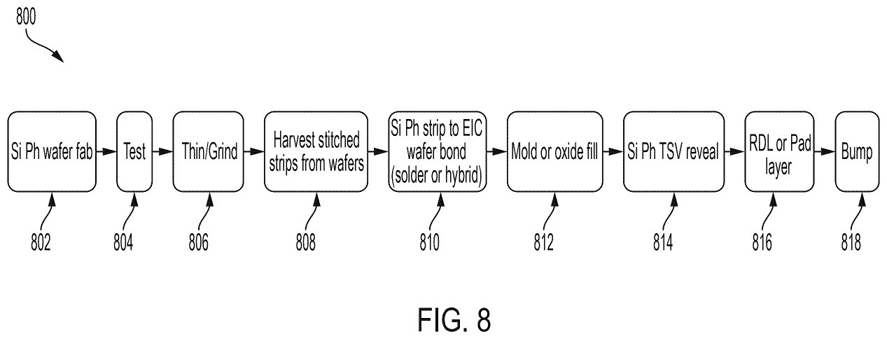

FIG. 8 illustrates an example method for manufacturing reconstituted wafers using a die-to-wafer bonding process, according to some embodiments. Method 800 begins at step 802, in which one or more silicon photonics wafers are fabricated. In some embodiments, identical reticle masks are used across the entire wafer, such that each reticle on the wafer is formed using the same photolithographic pattern. In some cases, multiple types of wafers may be fabricated, with each wafer comprising reticles formed using a single mask set.

At step 804, the reticles on each wafer are tested to identify KGDs and to flag non-functional reticles. Testing may include electrical and/or optical probing to ensure that only functional dies are selected for reconstitution.

At step 806, the wafers are processed to prepare for reconstitution. This may include thinning, grinding, and/or dicing the wafer to expose through-silicon vias (TSVs) within the reticles. These steps are typically performed prior to bonding. Dicing results in the formation of strips containing multiple KGDs.

At step 808, the diced strips are harvested and prepared for placement on a target substrate. At step 810, the strips are arranged in the desired configuration and bonded directly on an EIC wafer. The bonding may be performed using hybrid bonding, solder bonding, or other direct-attach techniques. In some embodiments, dummy reticles are used to fill unoccupied positions on the EIC wafer. In some examples, a spacing gap of approximately 40 to 100 microns in length may exist between adjacent strips following placement. At step 812, these inter-strip gaps are filled using a suitable filling material. In some embodiments, the fill material comprises an oxide or is applied via a molding process. Following gap fill, excess material may remain on the upper surface of the device. Accordingly, at step 814, the surface is planarized by grinding and/or chemical mechanical polishing (CMP) to remove the excess fill and expose TSVs within the photonic strips.

At step 816, a redistribution layer (RDL) and/or pad layer is formed on the polished surface to route electrical signals and provide interconnect points for external interfaces. Finally, at step 818, metal bumps are formed on top of the redistribution layer to enable electrical connectivity. These bumps may serve as solder balls or connection points for flip-chip packaging, for example.

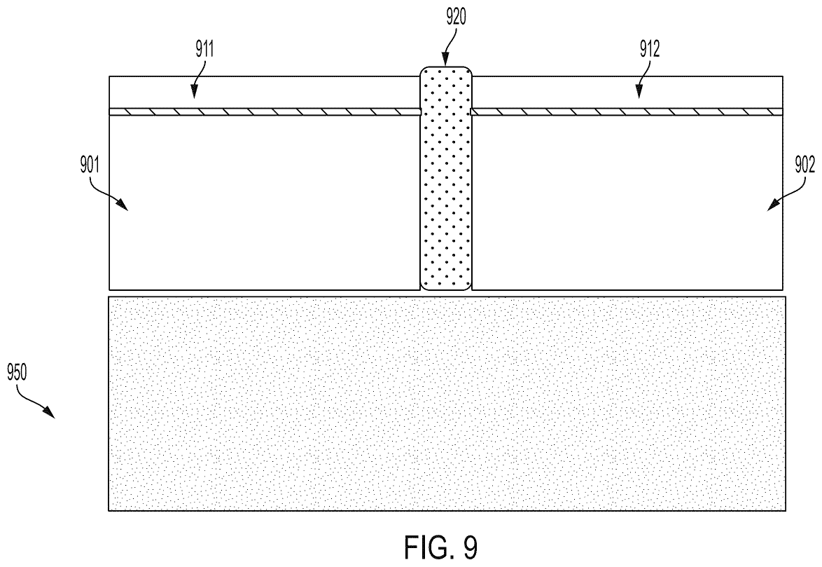

FIG. 9 illustrates an example in which waveguides from adjacent strips are optically coupled using an intermediate optical medium. This configuration may be applied to any of the reconstitution approaches described above, including wafer-to-wafer or die-to-wafer processes. As shown, two strips 901 and 902 are placed side-by-side, each including respective waveguides, 911 and 912. An optical material 920 is disposed between the two strips to bridge the gap and facilitate optical coupling between waveguides 911 and 912. Optical material 920 may form part of the filling material disposed in the gaps between, and surrounding, the strips (e.g., filling material 351 of FIG. 3B). As such, a portion of the filling material forms part of an inter-strip coupler (e.g., inter-strip coupler 327 of FIG. 3C). In some embodiments, optical material 920 includes an index-matching epoxy (IME), oxide, or other suitable polymeric or dielectric material selected to minimize optical loss at the interface. This material may be deposited after strip placement to fill the inter-strip region and align with the optical waveguides. The strips 901 and 902 may be supported on a substrate 950, which may be a temporary carrier wafer or an EIC. Use of a filling material allows waveguide from different strips to achieve low-loss optical coupling even in the presence of minor alignment tolerances or spacing variations introduced during reconstitution.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. A photonic device, comprising:
a plurality of strips, each of the plurality of strips comprising a plurality of contiguous reticles collectively forming a continuous photonic network, wherein the plurality of strips are extracted from one or more source wafers; and
a filling material disposed between the plurality of strips.

2. The photonic device of claim 1, wherein the filling material surrounds the plurality of strips.

3. The photonic device of claim 2, wherein the filling material has a rounded edge profile where the filling material surrounds the plurality of strips.

4. The photonic device of claim 1, wherein a first strip of the plurality of strips extends along a first axis and a second strip of the plurality of strips extends along a second axis perpendicular to the first axis.

5. The photonic device of claim 1, further comprising:
a substrate, wherein the plurality of strips are adhered to the substrate, wherein the substrate comprises a carrier wafer or an electronic integrated circuit (EIC).

6. The device of claim 1, wherein the plurality of strips comprises:
a first subset of strips of a first type; and
a second subset of strips of a second type, wherein the first type is different from the second type.

7. A photonic device, comprising:
a plurality of strips, each of the plurality of strips comprising a plurality of contiguous reticles collectively forming a continuous photonic network, wherein the plurality of strips comprises at least a first strip extracted from a first source wafer and a second strip extracted from a second source wafer, wherein the first strip comprises an intra-strip coupler optically coupling a first reticle of the first strip to a second reticle of the first strip; and
an inter-strip coupler optically coupling the first strip to the second strip.

8. The photonic device of claim 7, further comprising a filling material surrounding the plurality of strips.

9. The photonic device of claim 8, wherein the filling material has a rounded edge profile where the filling material surrounds the plurality of strips.

10. The photonic device of claim 8, wherein a portion of the filling material is disposed between the first strip and the second strip and forms part of the inter-strip coupler.

11. The photonic device of claim 7, further comprising:
a substrate, wherein the plurality of strips are adhered to the substrate, wherein the substrate comprises a carrier wafer or an electronic integrated circuit (EIC).

12. The photonic device of claim 7, wherein the first strip is of a first type and the second strip is of a second type different from the first type.

13. The photonic device of claim 12, wherein:
the first strip of the first type comprises a v-groove; and
the second strip of the second type lacks v-grooves.

14. A method of manufacturing a photonic device, the method comprising:
fabricating a first silicon wafer comprising a first plurality of reticles;
testing each of the first plurality of reticles to identify functional reticles;
singulating a first plurality of strips from the first silicon wafer, wherein each of the first plurality of strips comprises a plurality of functional reticles from among the identified functional reticles; and
forming a continuous photonic network by attaching the first plurality of strips together.

15. The method of claim 14, further comprising:
fabricating a second silicon wafer comprising a second plurality of reticles;
testing each of the second plurality of reticles to identify functional reticles; and
singulating a second plurality of strips from the second silicon wafer, wherein each of the second plurality of strips comprises a plurality of functional reticles of the identified functional reticles of the second silicon wafer;
wherein forming the continuous photonic network comprises attaching the first plurality of strips to the second plurality of strips.

16. The method of claim 14, wherein attaching the first plurality of strips together comprises:
adhering the first plurality of strips to a carrier wafer using an adhesive;
filling gaps between the first plurality of strips with a filling material; and
removing the first plurality of strips and the filling material from the carrier wafer by removing the adhesive.

17. The method of claim 16, wherein removing the plurality of strips and the filling material from the carrier wafer by removing the adhesive comprises exposing the adhesive to laser light and/or heating the adhesive.

18. The method of claim 16, wherein filling the gaps between the first plurality of strips with the filling material comprises surrounding the first plurality of strips with the filling material.

19. The method of claim 18, wherein surrounding the first plurality of strips with the filling material comprises defining a rounded edge profile where the filling material surrounds the first plurality of strips.

20. The method of claim 14, wherein attaching the plurality of strips together comprises:
attaching the plurality of strips to an electronic integrated circuit (EIC); and
filling gaps between the plurality of strips with a filling material.
